(19) United States
(12) Patent Application Publication
(10) Pub. No.: US 2026/0052698 A1
(43) Pub. Date: Feb. 19, 2026

(54) MEMORY DEVICE AND METHOD FOR FORMING THE SAME

(71) Applicant: TAIWAN SEMICONDUCTOR MANUFACTURING COMPANY, LTD., Hsinchu (TW)

(72) Inventors: Atul KATOCH, Kanata (CA); Cormac Michael O’CONNELL, Kanata (CA)

(73) Assignee: TAIWAN SEMICONDUCTOR MANUFACTURING COMPANY, LTD., Hsinchu (TW)

(21) Appl. No.: 18/806,390

(22) Filed: Aug. 15, 2024

(51) Int. Cl. H10B 53/30; H10B 61/00

(52) U.S. Cl. CPC H10B 53/30; H10B 61/22

(57) ABSTRACT

A memory device includes a substrate. A transistor is over a front side of the substrate. A front side interconnect structure is over the front side of the substrate and electrically connected with the transistor. A storage element is at a position below the transistor and electrically connected with the transistor, wherein the storage element comprises a first electrode, a second electrode, and a data storage layer between the first electrode and the second electrode.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic circuit diagram of a memory device in accordance with some embodiments of the present disclosure.

FIG. 2 is a cross-sectional view of a memory device in accordance with some embodiments of the present disclosure.

FIGS. 3 to 8 show cross-sectional views of intermediate structures at respective stages during an example method for forming a semiconductor device in accordance with some embodiments.

FIG. 9 is a cross-sectional view of a memory device in accordance with some embodiments of the present disclosure.

FIGS. 10 to 11 show cross-sectional views of intermediate structures at respective stages during an example method for forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

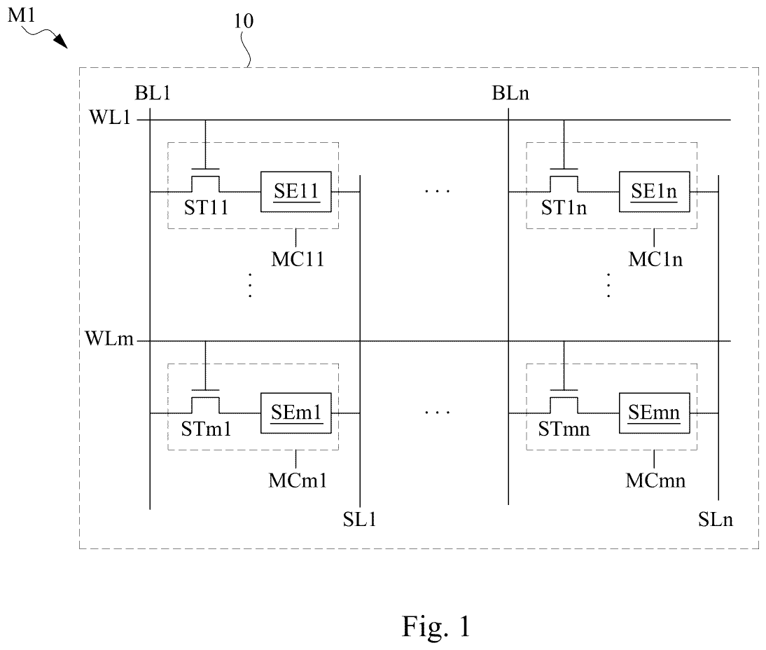

FIG. 1 is a schematic circuit diagram of a memory device in accordance with some embodiments of the present disclosure. The memory device M1 may include a memory array 10, which includes a plurality of memory cells MC11, MC1n, MCm1 . . . to MCmn that are coupled to a plurality of word lines WL1 through WLm, a plurality of bit lines BL1 through BLn and a plurality of source lines SL1 through SLn, where m and n are positive integers. For example, the memory cell MC11 is coupled to the corresponding word line WL1, the corresponding bit line BL1, and the corresponding source line BL1. Memory operations such as a read operation or a write operation are performed to the memory cells of the memory array 10 through the word line WL1 through WLm, the bit line BL1 through BLn and the source line SL1 through SLn. For example, appropriate word line voltages, bit line voltages and source line voltages are applied to the corresponding word line WL1, the corresponding bit line BL1 and the corresponding source line SL1 to perform the memory operations to the memory cell MC11.

In some embodiments, each of the memory cells MC11 through MCmn includes a select transistor (e.g., select transistor ST11, ST1n, STm1 . . . STmn) and a storage element (e.g., storage element SE11, SE1n, SEm1 . . . SEmn), where the select transistor is configured to control an access to the memory cell and the storage element is configured to store data of the memory cell. For example, the memory cell MC11 includes a select transistor ST11 and a storage element SE11 being coupled to the select transistor ST11. In another example, the memory cell MCmn includes a select transistor STmn and a storage element SEmn being coupled to the select transistor STmn. The select transistor in each memory cell is coupled between a corresponding bit line and a corresponding storage element, and a gate terminal of the select transistor is coupled to a corresponding word line. For example, the source/drain terminal of the select transistor ST11 of the memory cell MC11 is coupled to the bit line BL1 and the other source/drain terminal of the select transistor ST11 of the memory cell MC11 is coupled to the source line SL1 through the storage element SE11, and the gate terminal of the select transistor ST11 is coupled to the word line WL1. In some embodiments, a threshold voltage of a memory cell is a minimum gate-to-source voltage that is needed to create a conducting path between the source and drain terminals of the select transistor in the memory cell. For example, the threshold voltage of the memory cell MC11 is the minimum gate-source voltage that is needed to create a conducting path between the source and drain terminals of the select transistor M11 of the memory cell MC11.

In some embodiments, each memory cell of the memory array 10 is a dynamic random access memory (DRAM) cell, a ferroelectric random access memory (FeRAM) cell, a magnetoresistive random-access memory (MRAM) cell, a resistive random access memory (RRAM) cell, a conductive-bridging random access memory (CBRAM) cell, or a phase-change random access memory (PCRAM) cell, the present disclosure is not limited thereto.

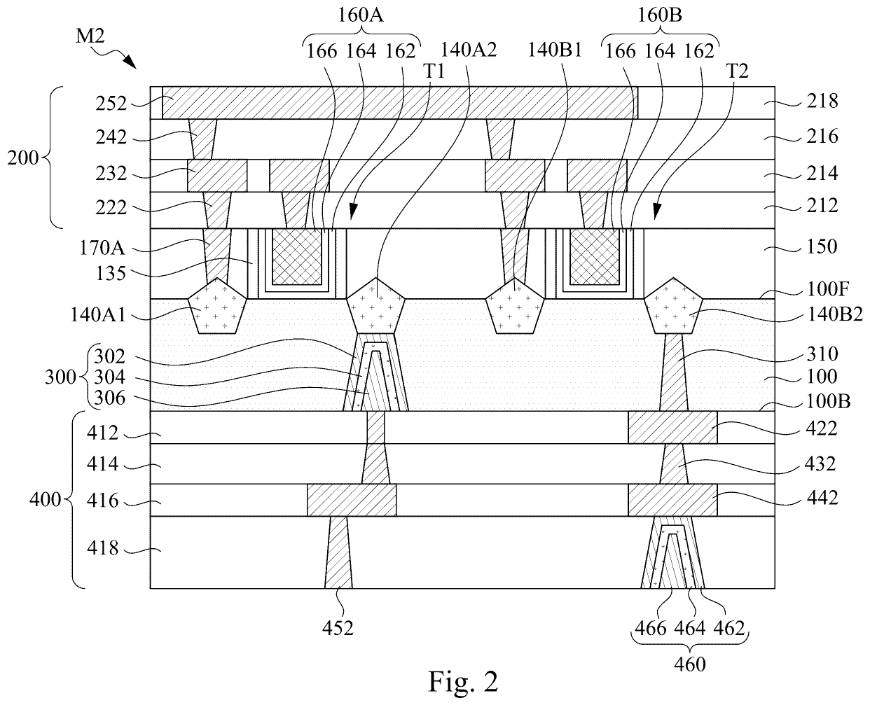

FIG. 2 is a cross-sectional view of a memory device in accordance with some embodiments of the present disclosure. Shown there is a memory device M2. In greater detail, the memory device M2 of FIG. 2 is an exemplary embodiment of the memory device M1 of FIG. 1.

The memory device M2 includes a substrate 100. The substrate 100 includes a front side 100F and a back side 100B opposite to the front side 100F. The substrate 100 generally include crystalline semiconductor material, such as silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), or combinations thereof.

The memory device M2 further includes a transistor T1 and a transistor T2 disposed on the front side 100F of the substrate 100. In some embodiments, the transistors T1 and T2 each can function as the select transistor of a memory cell as discussed in FIG. 1. In some embodiments, the transistor T1 may include a gate structure 160A over the substrate 100 and source/drain epitaxial structures 140A1 and 140A2 disposed over the substrate 100 and on opposite sides of the gate structure 160A. Similarly, the transistor T2 may include a gate structure 160B over the substrate 100 and source/drain epitaxial structures 140B1 and 140B2 disposed over the substrate 100 and on opposite sides of the gate structure 160B.

In some embodiments, each of the gate structures 160A and 160B may include a gate dielectric layer 162, a work function metal layer 164 over the gate dielectric layer 162, and a filling metal 166 over the work function metal layer 164. The gate dielectric layer 162 may include an interfacial layer and a high-k dielectric layer over the interfacial layer. Examples of interfacial material include silicon oxide (SiO₂). Examples of high-k dielectric material include HfO₂, HfSiO, HfSiON, HfTaO, HfTiO, HfZrO, zirconium oxide, aluminum oxide (Al₂O₃), titanium oxide, hafnium dioxide-alumina (HfO₂—Al₂O₃) alloy, other suitable high-k dielectric materials, and/or combinations thereof. In some embodiments, the work function metal layer 164 may include titanium-based material or tantalum-based material, such as Ti, TiN, Ta, TaN, or the like. In some embodiments, the filling metal 166 may include metal, such as tungsten (W), aluminum (Al), copper (Cu), silver (Ag), or the like.

The memory device M2 further includes gate spacers 135 on opposite sidewalls of each of the gate structures 160A and 160B. The gate spacers 135 may be used to offset the gate structure 160A from the source/drain epitaxial structures 140A1 and 140A2, and to offset the gate structure 160B from the source/drain epitaxial structures 140B1 and 140B2, respectively. In some embodiments, the gate spacers 135 may include silicon oxide, silicon nitride, silicon oxynitride, the like, or combinations thereof.

The memory device M2 further includes an interlayer dielectric (ILD) layer 150 over the substrate 100, covering the source/drain epitaxial structures 140A1, 140A2, 140B1, and 140B2, and laterally surrounding the gate structures 160A and 160B. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

The memory device M2 further includes a source/drain contact 170A and a source/drain contact 170B in the ILD layer 150 and electrically connected with the source/drain epitaxial structure 140A1 and the source/drain epitaxial structure 140B1, respectively. In some embodiments, each of the source/drain contacts 170A and 170B may include a contact plug and a diffusion barrier lining the contact plug. In some embodiments, the contact plug may include suitable conductive material such as W, Al, Cu, Ru, Ni, Co, alloys of these, combinations thereof, and the like. The diffusion barrier may include titanium-based material or tantalum-based material, such as Ti, TiN, Ta, TaN, or other suitable metals, or their alloys. In some embodiments, the ILD layer 150 is free of source/drain contacts that are electrically connected with the source/drain epitaxial structures 140A2 and 140B2. That is, an entirety of the top surfaces of the source/drain epitaxial structures 140A2 and 140B2 may be covered by the ILD layer 150.

The memory device M2 further includes a front side interconnect structure 200 disposed over the ILD layer 150 and electrically connected with the transistors T1 and T2. In some embodiments, the front side interconnect structure 200 may include dielectric layers 212, 214, 216, and 218 stacked one above another. In some embodiments, the dielectric layers 212, 214, 216, and 218 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the dielectric layers 212, 214, 216, and 218 can also be referred to as inter-metal dielectric (IMD) layers.

With respect to the dielectric layer 212, a plurality of conductive vias 222 are disposed in the dielectric layer 212. In some embodiments, portions of the conductive vias 222 electrically connected with the gate structures 160A and 160B can be referred to as gate vias, while portions of the conductive vias 222 electrically connected with the source/drain contacts 170A and 170B can be referred to as source/drain vias.

With respect to the dielectric layer 214, a plurality of metal lines 232 are disposed in the dielectric layer 214. In some embodiments, portions of the metal lines 232 that are electrically connected with the gate structures 160A and 160B may function as word lines of a memory array (e.g., the word lines as discussed in FIG. 1). In other embodiments, because the gate terminal of the select transistor is connected with a corresponding word line (see FIG. 1), the gate structures 160A and 160B shown in FIG. 2 can also function as the word lines, the present disclosure is not limited thereto. However, it is understood that one skilled in the art can form the word lines at a desired position. In some embodiments, the word lines are disposed on the front side 100F of the substrate 100.

With respect to the dielectric layer 216, a plurality of conductive vias 242 are disposed in the dielectric layer 216. The conductive vias 242 may be electrically connected with the corresponding metal lines 232 in the dielectric layer 214.

With respect to the dielectric layer 218, at least a metal line 252 is disposed in the dielectric layer 218. In some embodiments, it can be seen that the metal line 252 is electrically connected with the source/drain epitaxial structures 140A1 and 140B1. In some embodiments, the metal line 252 can also be referred to as a bit line of a memory array (e.g., the bit line as discussed in FIG. 1). However, it is understood that one skilled in the art can form the bit line(s) at a desired position. In some embodiments, the bit line(s) are disposed on the front side 100F of the substrate 100.

Here, the term “via” may be a conductive feature having longest dimension extending vertically, and the term “metal line” may be a conductive feature having longest dimension extending laterally, and thus the via may conduct current vertically and are used to electrically connect two conductive features located at vertically adjacent levels, whereas the metal line may conduct current laterally and are used to distribute electrical signals and power within one level. In some embodiments, the vias and the metal lines discussed above can be made of suitable metal such as copper, aluminum, tungsten, combinations thereof, or the like.

The memory device M2 further includes a storage element 300 disposed in the substrate 100 and electrically connected with the source/drain epitaxial structure 140A2 of the transistor T1. In some embodiments, the storage element 300 may include a first electrode 302, a second electrode 306, and a data storage layer 304 sandwiched between the first electrode 302 and the second electrode 306. In some embodiments, the storage element 300 may be exposed at the back side 100B of the substrate 100. In some embodiments, the storage element 300 is positioned below the source/drain epitaxial structure 140A2 of the transistor T1.

In some embodiments, the data storage layer 304 may be, for example, a material or structure that is able to store a data bit (e.g., a “1” or “0”) by its resistance, and that reversibly changes between a high resistance state and a low resistance state depending upon a voltage applied across the data storage element. In some embodiments, the first electrode 302 and the second electrode 306 may include copper (Cu), platinum (Pt), iridium (Ir), gold (Au), tungsten (W), some other metal, titanium-nitride (TiN), some other conductive metal nitride, some other conductive material, or combination thereof.

In some embodiments where the memory device M2 is a dynamic random access memory (DRAM) device, the storage element 300 may be a metal-insulator-metal (MIM) capacitor. In such embodiments, the data storage layer 304 may include a dielectric material, such as silicon dioxide (SiO₂), a high-k dielectric, or some other dielectric. As used herein, a high-k dielectric may be a dielectric with a dielectric constant greater than about 3.9, 5, 10, 15, or 20.

In some embodiments where the memory device M2 is a ferroelectric random access memory (FeRAM) device, the storage element 300 may be a ferroelectric capacitor. In such embodiments, the data storage layer 304 may include a ferroelectric material and may also be referred to as a ferroelectric layer. A ferroelectric material has a nonlinear relationship between the applied electric field and the stored charge. Specifically, the ferroelectric characteristic has the form of a hysteresis loop. Semi-permanent electric dipoles are formed in the crystal structure of the ferroelectric material. When an external electric field is applied across the ferroelectric material, the dipoles tend to align themselves with the field direction, produced by small shifts in the positions of atoms and shifts in the distributions of electronic charge in the crystal structure. When the external electric field is removed, the dipoles of the ferroelectric material retain their polarization state. In some embodiments, the ferroelectric material may include hafnium oxide (HfOₓ) doped with dopant(s) such as Zr, Si, La, hafnium zirconium oxide (HZO), AlScN, ZrOₓ, ZrOₓPb₃Ge₅O₁₁ (PGO), lead zirconatetitanate (PZT), SrBizTa₂O₉(SBT or SBTO), SrB₄O₇(SBO), SrₐBi_{b}Ta_{c}Nb_{d}Oₓ(SBTN), SrTiO₃(STO), BaTiO₃(BTO), (BiₓLa_{y})Ti₃O₁₂(BLT), LaNiO₃(LNO), YMnO₃, ZrO₂, zirconium silicate, ZrAlSiO, hafnium oxide (HfO₂), hafnium silicate, HfAlO, LaAlO, lanthanum oxide, Ta₂O₅, and/or other suitable ferroelectric material, or combinations thereof.

In some embodiments where the memory device M2 is a magnetoresistive random access memory (MRAM) device, data storage layer 304 may be a magnetic tunnel junction (MTJ) stack. In such embodiments, the data storage layer 304 may include a free layer, a pinned layer, and a tunnel barrier layer sandwiched between the free layer and the pinned layer. The pinned layer may be made of, for example but not limited to, CoFeB, CoFeTa, NiFe, Co, CoFe, CoPt, CoPd, FePt, Ru, Ta, TaN, or other alloys of Ni, Co and Fe, other suitable materials, or any combination thereof. The free layer may be made of, for example but not limited to, CoFeB, CoFeTa, NiFe, Co, CoFe, CoPt, CoPd, FePt, Ru, Ta, TaN, or other alloys of Ni, Co and Fe, other suitable materials, or a combination thereof. The tunnel barrier layer may be made of a dielectric material, such as magnesium oxide (MgO), aluminum oxide (AlOₓ (e.g., Al₂O₃)), aluminum nitride (AlN), aluminum oxynitride (AlON), other suitable materials, or a combination thereof.

In some embodiments where the memory device M2 is a resistive random access memory (RRAM) device, the data storage layer 304 may include a variable resistance element, which may include a resistance switching layer and a capping layer over the resistance switching layer. In some embodiments, the resistance switching layer may include nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), for example. In some embodiments, the capping layer may include platinum (Pt), aluminum copper (AlCu), titanium nitride (TiN), gold (Au), titanium (Ti), tantalum (Ta), tantalum nitride (TaN), tungsten (W), tungsten nitride (WN), or copper (Cu).

In some embodiments where the memory device M2 is a conductive-bridging random access memory (CBRAM) device, the data storage layer 304 may include solid electrolyte material.

In some embodiments where the memory device M2 is a phase-change random access memory (PCRAM) device, the data storage layer 304 may include a phase-change material, such as a chalcogenide material. Examples of the chalcogenide material include GeSbTe (GST) or GeSbTeX, in which X is a material such as Ag, Sn, In, Si, N, or the like.

The memory device M2 further includes a through-substrate-via (TSV) 310 in the substrate 100 and electrically connected with the source/drain epitaxial structure 140B2 of the transistor T2. In some embodiments, the TSV 310 may be exposed at the back side 100B of the substrate 100. In some embodiments, the TSV 310 is positioned below the source/drain epitaxial structure 140B2 of the transistor T2. In some embodiments where the substrate 100 is made of silicon, the through-substrate-via (TSV) 310 can also be referred to as through-silicon-via (TSV). In some embodiments, the TSV 310 may include copper (Cu), platinum (Pt), iridium (Ir), gold (Au), tungsten (W), some other metal, titanium-nitride (TiN), some other conductive metal nitride, some other conductive material, or combination thereof.

The memory device M2 further includes a back side interconnect structure 400 disposed on the back side 100B of the substrate 100 and electrically connected with the transistors T1 and T2. In some embodiments, the back side interconnect structure 400 may include dielectric layers 412, 414, 416, and 418 stacked one above another. In some embodiments, the dielectric layers 412, 414, 416, and 418 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the dielectric layers 412, 414, 416, and 418 may also be referred to as back side inter-metal dielectric (IMD) layers.

With respect to the dielectric layer 412, a plurality of metal lines 422 are disposed in the dielectric layer 412 and electrically connected with the storage element 300 and the TSV 310, respectively. In some embodiments, the portion of the metal lines 422 electrically connected with the storage element 300 can also function as the source line of a memory array (e.g., the source line as discussed in FIG. 1).

With respect to the dielectric layer 414, a plurality of conductive vias 432 are disposed in the dielectric layer 414. The conductive vias 432 may be electrically connected with the corresponding metal lines 422 in the dielectric layer 412.

With respect to the dielectric layer 416, a plurality of metal lines 442 are disposed in the dielectric layer 416. The metal lines 442 may be electrically connected with the corresponding conductive vias 432 in the dielectric layer 414.

With respect to the dielectric layer 418, at least a conductive via 452 is disposed in the dielectric layer 418 and electrically with the corresponding metal line 442 in the dielectric layer 416. Moreover, a storage element 460 is disposed in the dielectric layer 418 and electrically connected with the source/drain epitaxial structure 140B2 of the transistor T2 through other conductive elements in the back side interconnect structure 400 and the TSV 310. In some embodiments, the storage element 460 may include a first electrode 462, a second electrode 466, and a data storage layer 464 sandwiched between the first electrode 462 and the second electrode 466. In some embodiments, the storage element 460 is positioned below the source/drain epitaxial structure 140B2 of the transistor T2. In some embodiments, the back side interconnect structure 400 may further include a source line (not shown) below and electrically connected with the storage element 460.

In some embodiments, the data storage layer 464 may be, for example, a material or structure that is able to store a data bit (e.g., a “1” or “0”) by its resistance, and that reversibly changes between a high resistance state and a low resistance state depending upon a voltage applied across the data storage element. In some embodiments, the first electrode 462 and the second electrode 466 may include copper (Cu), platinum (Pt), iridium (Ir), gold (Au), tungsten (W), some other metal, titanium-nitride (TiN), some other conductive metal nitride, some other conductive material, or combination thereof. In some embodiments, the data storage layer 464 may include a same material as the data storage layer 304 as discussed above, and thus relevant details will not be repeated for brevity.

It is understood that the structure discussed herein is merely used to explain, and the present disclosure is not limited thereto. In some embodiments, parts of the storage elements of the memory cells may be positioned in the substrate 100, while parts of the storage elements of the memory cells may be positioned in the back side interconnect structure 400. However, in other embodiments, all of the storage elements of the memory cells may be positioned in the substrate 100. In yet some other embodiments, all of the storage elements of the memory cells may be positioned in the back side interconnect structure 400.

In some embodiments of the present disclosure, a memory device is provided by positioning the storage elements of the memory cells either embedded in the substrate or on the back side of the substrate. Such modification may simplify the manufacturing process of the front side devices and may not impact the electrical routing of the front side devices. Moreover, such modification may also be beneficial for device shrinkage.

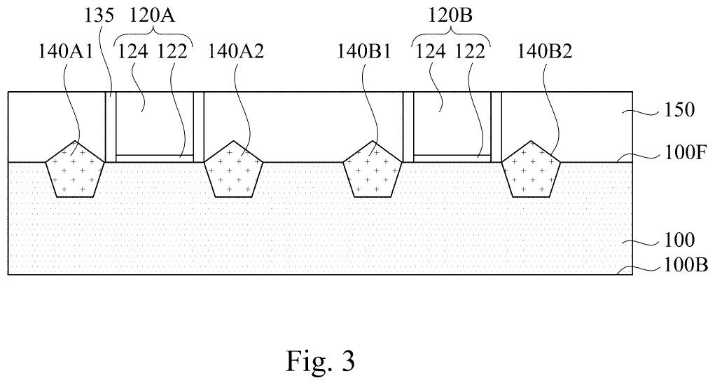

FIGS. 3 to 8 show cross-sectional views of intermediate structures at respective stages during an example method for forming a semiconductor device in accordance with some embodiments. In greater detail, FIGS. 3 to 8 illustrate a method for forming the memory device M2 as discussed in FIG. 2. Accordingly, similar elements will be labeled the same, and relevant details will not be repeated for brevity. Although FIGS. 3 to 8 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 3. Dummy gate structures 120A and 120B are formed over a substrate 100. In some embodiments, each of the dummy gate structures 120A and 120B includes a dummy gate dielectric 122 and a dummy gate electrode 124 over the dummy gate dielectric 122. The dummy gate dielectric 122 may be, for example, silicon oxide, silicon nitride, a combination thereof, or the like, and may be deposited or thermally grown according to acceptable techniques. The dummy gate electrode 124 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

Gate spacers 135 are formed on opposite sidewalls of the dummy gate structures 120A and 120B. In some embodiments, a spacer layer may be deposited blanket over the substrate 100. An anisotropic etching may be performed on the spacer layer to remove horizontal portions of the spacer layer, while leaving vertical portions of the spacer layer on opposite sidewalls of the dummy gate structures 120A and 120B as the gate spacers 135.

Source/drain epitaxial structures 140A1 and 140A2 are formed on opposite sidewalls of the dummy gate structures 120A, and source/drain epitaxial structures 140B1 and 140B2 are formed on opposite sidewalls of the dummy gate structures 120B. In some embodiments, the source/drain epitaxial structures 140A1, 140A2, 140B1, and 140B2 may be N-type epitaxial structures or P-type epitaxial structures. The N-type epitaxial structures may be doped with N-type dopants, such as phosphorus (P), arsenic (As), or antimony (Sb), or the like. The P-type epitaxial structures may be doped with P-type dopants, such as boron (B), gallium (Ga), indium (In), aluminium (Al), or the like.

An interlayer dielectric (ILD) layer 150 is formed over the substrate 100 and covering the source/drain epitaxial structures 140A1, 140A2, 140B1, and 140B2 and the dummy gate structures 120A and 120B. The ILD layer 150 can be formed using, for example, CVD, ALD or other suitable techniques. A planarization process, such as CMP, may be performed to remove excess material of the ILD layer 150 until the dummy gate structures 120A and 120B are exposed.

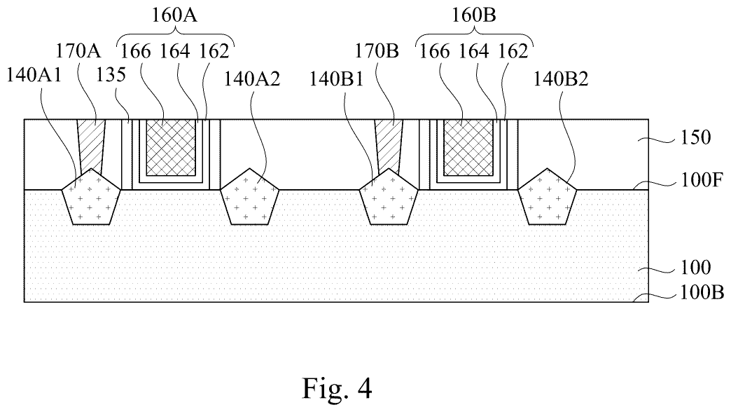

Reference is made to FIG. 4. The dummy gate structures 120A and 120B are replaced with metal gate structures 160A and 160B, respectively. In some embodiments, an etching process may be performed to remove the dummy gate structures 120A and 120B, so as to form gate trenches between each pair of the gate spacers 135. Then, layers of the metal gate structures 160A and 160B are deposited in the gate trenches. A planarization process, such as CMP, may be performed to remove excess materials of the metal gate structures 160A and 160B until the ILD layer 150 is exposed. After the metal gate structures 160A and 160B are formed, source/drain contacts 170A and 170B are formed in the ILD layer 150.

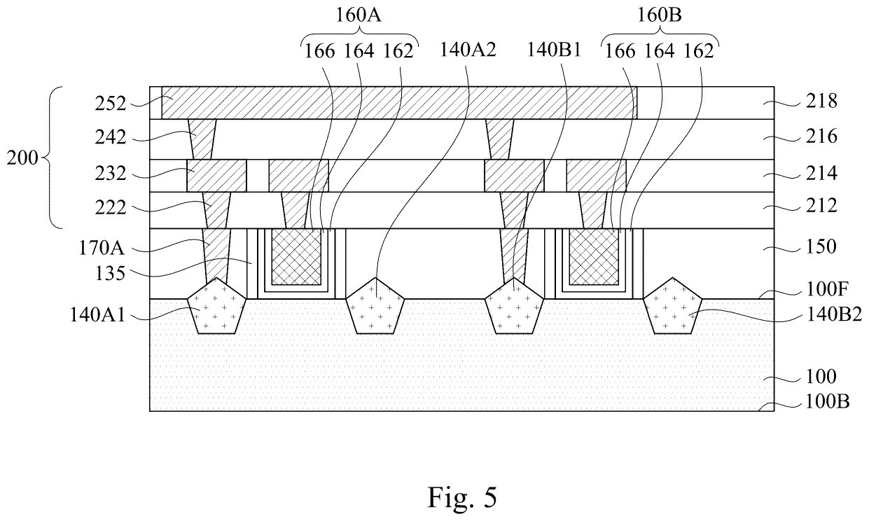

Reference is made to FIG. 5. A front side interconnect structure 200 is formed over the ILD layer 150. In some embodiments, a dielectric layer 212 may be deposited over the ILD layer 150. The dielectric layer 212 may be patterned to form openings within the dielectric layer 212, and conductive materials may be deposited in the openings of the dielectric layer 212 to form the conductive vias 222. Similarly, a dielectric layer 214 may be deposited over the dielectric layer 212, and metal lines 232 are formed in the dielectric layer 214. A dielectric layer 216 may be deposited over the dielectric layer 214, and conductive vias 242 are formed in the dielectric layer 216. A dielectric layer 218 may be deposited over the dielectric layer 216, and metal line 252 is formed in the dielectric layer 218.

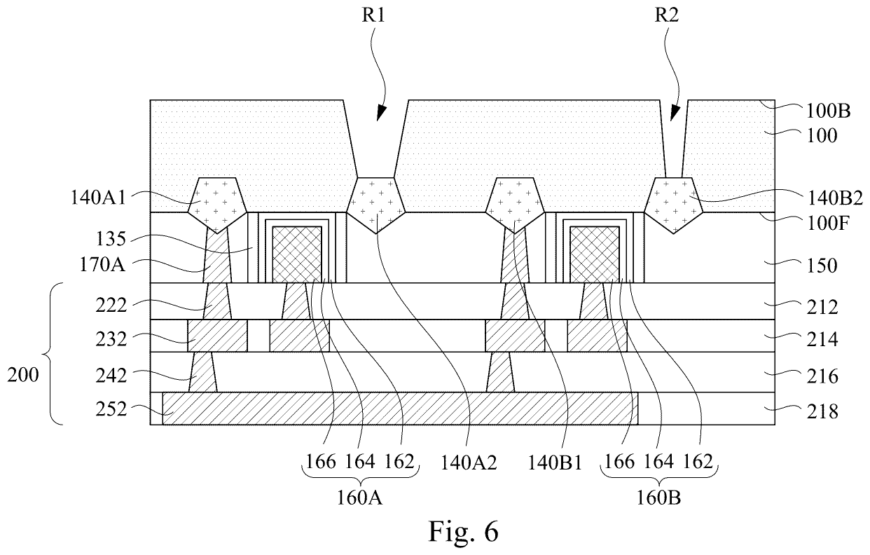

Reference is made to FIG. 6. After the front side interconnect structure 200 is formed, the structure of FIG. 5 may be flipped over by, for example, 180 degrees, such that the back side 100B of the substrate 100 faces upwardly. Then, a patterned mask (not shown) having openings is formed over the back side 100B of the substrate 100. An etching process is performed to remove portions of the substrate 100 through the openings of the patterned mask, so as to form recesses R1 and R2 in the substrate 100. In some embodiments, the recesses R1 and R2 may expose the source/drain epitaxial structures 140A2 and 140B2, respectively. In some embodiments, the recess R1 may be wider than the recess R2. In some embodiments, each of the recesses R1 and R2 may include a width decreasing toward the front side 100F of the substrate 100.

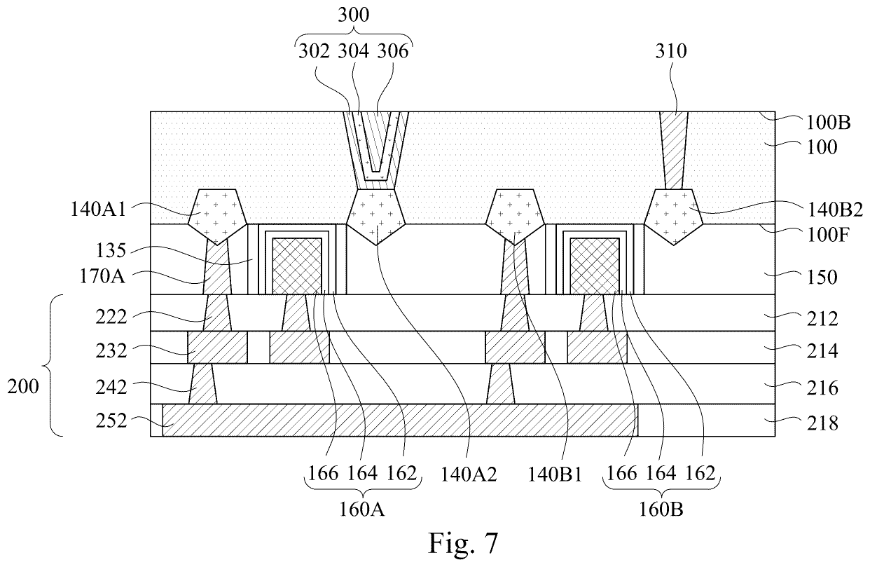

Reference is made to FIG. 7. A storage element 300 is formed in the recess R1 of the substrate 100, and a through-substrate-via (TSV) 310 is formed in the recess R2 of the substrate 100, respectively. In some embodiments, the first electrode 302, the data storage layer 304, and the second electrode 306 may be sequentially deposited in the recess R1. A planarization process may be performed to remove excess materials of the first electrode 302, the data storage layer 304, and the second electrode 306 until the back side 100B of the substrate 100 is exposed. As a result, a surface of the storage element 300 may be substantially level with the surface of the back side 100B of the substrate 100. In some embodiments, the first electrode 302 and the data storage layer 304 may also include a U-shape cross-sectional profile. In some embodiments, the storage element 300 may inherit the profile of the recess R1, and thus the storage element 300 may also include a width decreasing toward the front side 100F of the substrate 100.

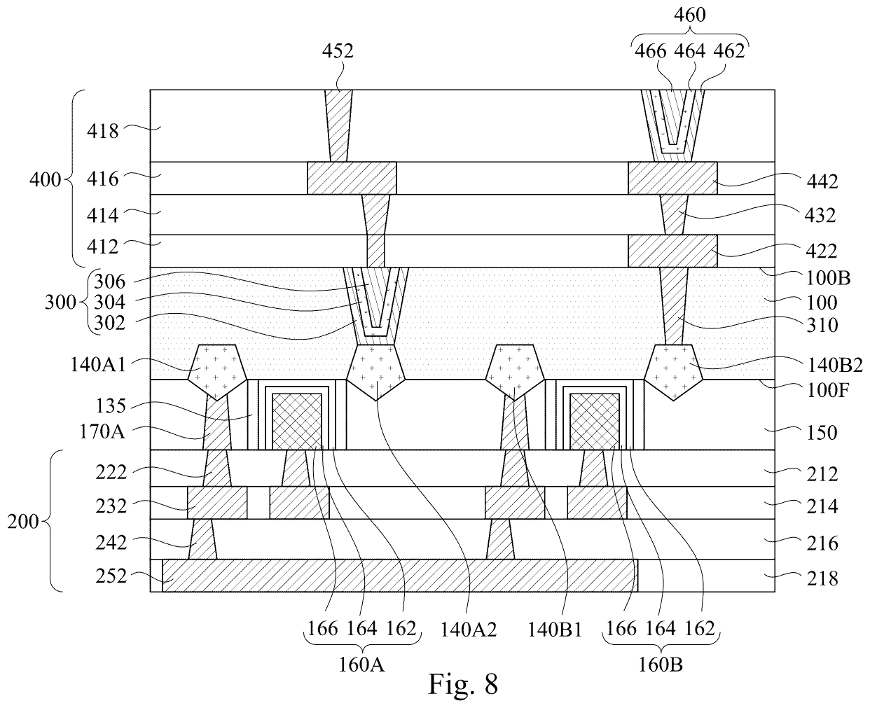

Reference is made to FIG. 8. A back side interconnect structure 400 is formed over the back side 100B of the substrate 100. In some embodiments, a dielectric layer 412 may be deposited over the back side 100B of the substrate 100. The dielectric layer 412 may be patterned to form openings within the dielectric layer 412, and conductive materials may be deposited in the openings of the dielectric layer 412 to form the metal lines 422. Similarly, a dielectric layer 414 may be deposited over the dielectric layer 412, and conductive vias 432 are formed in the dielectric layer 414. A dielectric layer 416 may be deposited over the dielectric layer 414, and metal lines 442 are formed in the dielectric layer 416. A dielectric layer 418 may be deposited over the dielectric layer 416, and a conductive via 452 and a storage element 460 are formed in the dielectric layer 418.

With respect to the formation of the storage element 460, a patterned mask (not shown) having openings may be formed over the dielectric layer 418. An etching process is performed to remove portions of the dielectric layer 418 through the openings of the patterned mask, so as to form recesses in the dielectric layer 418. In some embodiments, the first electrode 462, the data storage layer 464, and the second electrode 466 may be sequentially deposited in the recess of the dielectric layer 418. A planarization process may be performed to remove excess materials of the first electrode 462, the data storage layer 464, and the second electrode 466 until the dielectric layer 418 is exposed. As a result, a surface of the storage element 460 may be substantially level with the surface of the dielectric layer 418. In some embodiments, the first electrode 462 and the data storage layer 464 may also include a U-shape cross-sectional profile. In some embodiments, the storage element 460 may also include a width decreasing toward the front side 100F of the substrate 100.

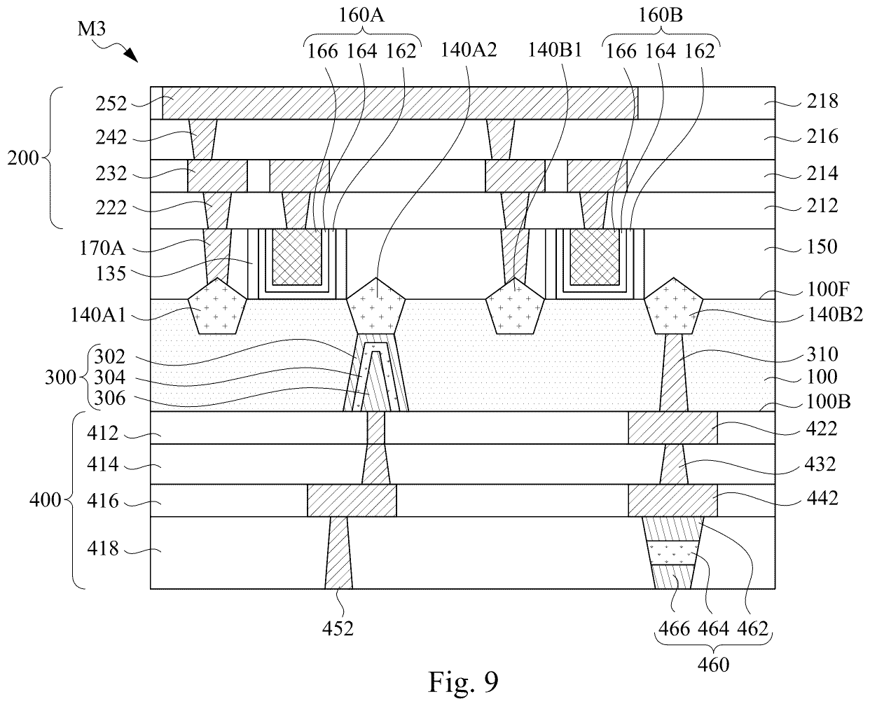

FIG. 9 is a cross-sectional view of a memory device in accordance with some embodiments of the present disclosure. Shown there is a memory device M3. The memory device M3 of FIG. 9 is similar to the memory device M2 of FIG. 2, the difference between the memory device M3 and memory device M2 is that the profiles of the first electrode 462, the data storage layer 464, and the second electrode 466 of the storage element 460. In the embodiments of FIG. 9, the first electrode 462, the data storage layer 464, and the second electrode 466 each may include a trapezoid cross-sectional profile. Moreover, the storage element 460 may include a width increasing toward the substrate 100. That is, the width of the storage element 300 in the substrate 100 and the width of the storage element 460 in the back side interconnect structure 400 may vary in opposite directions.

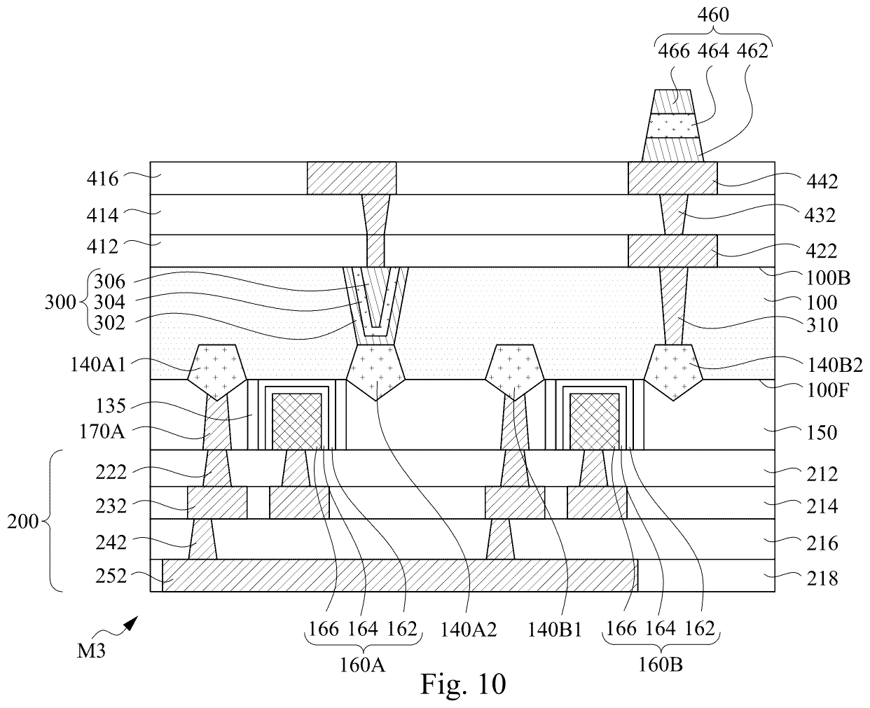

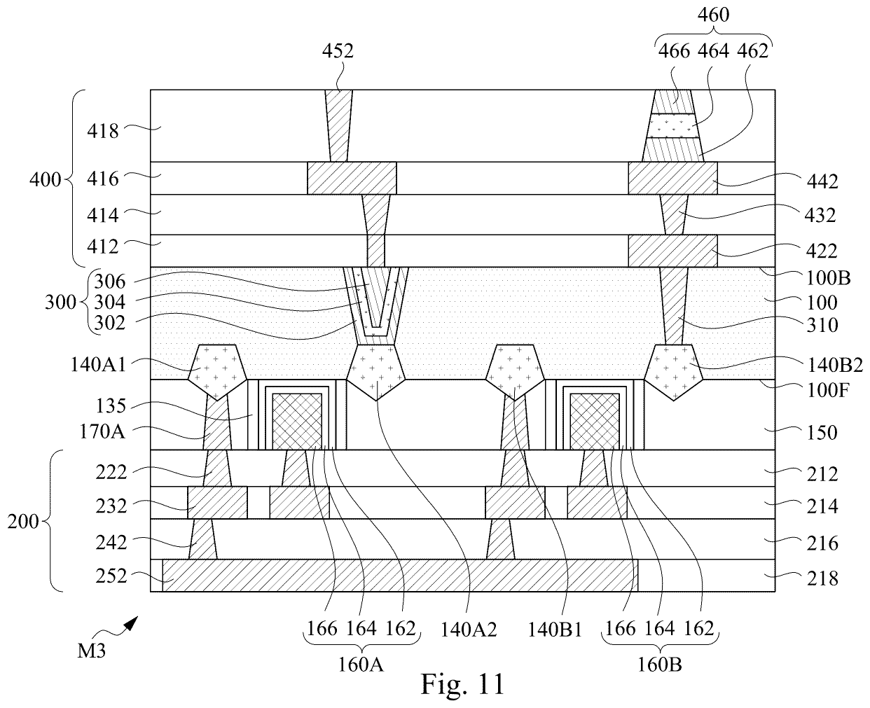

FIGS. 10 to 11 show cross-sectional views of intermediate structures at respective stages during an example method for forming a semiconductor device in accordance with some embodiments. In greater detail, FIGS. 10 to 11 illustrate a method for forming the memory device M3 as discussed in FIG. 9.

Reference is made to FIG. 10. Once the dielectric layer 416 is formed, layers of the first electrode 462, the data storage layer 464, and the second electrode 466 are sequentially deposited over the dielectric layer 416. Then, the layers of the first electrode 462, the data storage layer 464, and the second electrode 466 are patterned to form the storage element 460, and the resulting structure is shown in FIG. 10.

Reference is made to FIG. 11. A dielectric layer 418 is formed covering the storage element 460. A planarization process may be performed to remove excess material of the dielectric layer 418 until the storage element 460 is exposed. Afterwards, a conductive via 452 may be formed in the dielectric layer 418. In some embodiments, the width of the conductive via 452 and the width of the storage element 460 may vary in opposite directions.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a memory device by positioning the storage elements of the memory device either embedded in the substrate or on the back side of the substrate. Such modification may simplify the manufacturing process of the front side devices and may not impact the electrical routing of the front side devices. Moreover, such modification may also be beneficial for device shrinkage.

In some embodiments of the present disclosure, a memory device includes a substrate. A transistor is over a front side of the substrate. A front side interconnect structure is over the front side of the substrate and electrically connected with the transistor. A storage element is at a position below the transistor and electrically connected with the transistor, wherein the storage element comprises a first electrode, a second electrode, and a data storage layer between the first electrode and the second electrode.

In some embodiments, the storage element is embedded in the substrate.

In some embodiments, the storage element is vertically below and electrically connected with a source/drain structure of the transistor.

In some embodiments, the memory device further includes a back side interconnect structure over a back side of the substrate, wherein the storage element is disposed in the back side interconnect structure.

In some embodiments, the storage element is electrically connected with the transistor through a via embedded in the substrate.

In some embodiments, the memory device further includes a word line over the front side of the substrate and electrically connected with a gate of the transistor. A bit line is over the front side of the substrate and electrically connected with a source/drain structure of the transistor. A source line is over a back side of the substrate and electrically connected with another source/drain structure of the transistor.

In some embodiments, the data storage layer has a U-shape cross-sectional profile.

In some embodiments, the data storage layer comprises a dielectric material.

In some embodiments of the present disclosure, a memory device includes a substrate having a front side and a back side opposite to the front side. A first transistor and a second transistor are over the front side of the substrate. A front side interconnect structure is over the front side of the substrate and electrically connected with the first and the second transistors. A back side interconnect structure is over the back side of the substrate and electrically connected with the first and the second transistors. A first storage element is embedded in the substrate and electrically connected with the first transistor. A second storage element is in the back side interconnect structure and electrically connected with the second transistor.

In some embodiments, the first storage element and the second storage element each includes a first electrode, a second electrode, and a data storage layer between the first electrode and the second electrode.

In some embodiments, the data storage layer is a dielectric material.

In some embodiments, the data storage layer is a ferroelectric material.

In some embodiments, the data storage layer includes a magnetic tunnel junction (MTJ) stack.

In some embodiments, the data storage layer includes a resistance switching material, a phase-change material, or a solid electrolyte material.

In some embodiments, the memory device further includes a word line over the front side of the substrate and electrically connected with a gate of the first transistor. A bit line is over the front side of the substrate and electrically connected with a source/drain structure of the first transistor. A source line is over the back side of the substrate and electrically connected with another source/drain structure of the first transistor.

In some embodiments of the present disclosure, a method includes forming a transistor from a front side of a substrate; forming a front side interconnect structure over the front side of the substrate and electrically connected with the transistor; flipping over the substrate such that a back side of the substrate faces upwardly; and forming a storage element from the back side of the substrate and electrically connected with the transistor.

In some embodiments, forming the storage element from the back side of the substrate comprises performing an etching process on the back side of the substrate to form a recess in the substrate; and forming the storage element in the recess.

In some embodiments, forming the storage element in the recess comprises sequentially depositing a first electrode, a data storage layer, and a second electrode in the recess.

In some embodiments, forming the storage element from the back side of the substrate comprises forming a dielectric layer over the back side of the substrate; and forming the storage element in the dielectric layer.

In some embodiments, the method further includes forming a via in the substrate, wherein the storage element is electrically connected with the transistor through the via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate;
a transistor over a front side of the substrate;
a front side interconnect structure over the front side of the substrate and electrically connected with the transistor; and
a storage element at a position below the transistor and electrically connected with the transistor, wherein the storage element comprises a first electrode, a second electrode, and a data storage layer between the first electrode and the second electrode.

2. The memory device of claim 1, wherein the storage element is embedded in the substrate.

3. The memory device of claim 1, wherein the storage element is vertically below and electrically connected with a source/drain structure of the transistor.

4. The memory device of claim 1, further comprising a back side interconnect structure over a back side of the substrate, wherein the storage element is disposed in the back side interconnect structure.

5. The memory device of claim 4, wherein the storage element is electrically connected with the transistor through a via embedded in the substrate.

6. The memory device of claim 1, further comprising:
a word line over the front side of the substrate and electrically connected with a gate of the transistor;
a bit line over the front side of the substrate and electrically connected with a source/drain structure of the transistor; and
a source line over a back side of the substrate and electrically connected with another source/drain structure of the transistor.

7. The memory device of claim 1, wherein the data storage layer has a U-shape cross-sectional profile.

8. The memory device of claim 1, wherein the data storage layer comprises a dielectric material.

9. A memory device, comprising:
a substrate having a front side and a back side opposite to the front side;
a first transistor and a second transistor over the front side of the substrate;
a front side interconnect structure over the front side of the substrate and electrically connected with the first and the second transistors;
a back side interconnect structure over the back side of the substrate and electrically connected with the first and the second transistors;
a first storage element embedded in the substrate and electrically connected with the first transistor; and
a second storage element in the back side interconnect structure and electrically connected with the second transistor.

10. The memory device of claim 9, wherein the first storage element and the second storage element each includes a first electrode, a second electrode, and a data storage layer between the first electrode and the second electrode.

11. The memory device of claim 10, wherein the data storage layer is a dielectric material.

12. The memory device of claim 10, wherein the data storage layer is a ferroelectric material.

13. The memory device of claim 10, wherein the data storage layer includes a magnetic tunnel junction (MTJ) stack.

14. The memory device of claim 10, wherein the data storage layer includes a resistance switching material, a phase-change material, or a solid electrolyte material.

15. The memory device of claim 9, further comprising:
a word line over the front side of the substrate and electrically connected with a gate of the first transistor;
a bit line over the front side of the substrate and electrically connected with a source/drain structure of the first transistor; and
a source line over the back side of the substrate and electrically connected with another source/drain structure of the first transistor.

16. A method, comprising:
forming a transistor from a front side of a substrate;
forming a front side interconnect structure over the front side of the substrate and electrically connected with the transistor;
flipping over the substrate such that a back side of the substrate faces upwardly; and
forming a storage element from the back side of the substrate and electrically connected with the transistor.

17. The method of claim 16, wherein forming the storage element from the back side of the substrate comprises:
performing an etching process on the back side of the substrate to form a recess in the substrate; and
forming the storage element in the recess.

18. The method of claim 17, wherein forming the storage element in the recess comprises sequentially depositing a first electrode, a data storage layer, and a second electrode in the recess.

19. The method of claim 16, wherein forming the storage element from the back side of the substrate comprises:
forming a dielectric layer over the back side of the substrate; and
forming the storage element in the dielectric layer.

20. The method of claim 19, further comprising forming a via in the substrate, wherein the storage element is electrically connected with the transistor through the via.
